(19) United States
(12) Patent Application Publication
(10) Pub. No.: US 2012/0008287 A1
(43) Pub. Date: Jan. 12, 2012

(54) Electronic component module and method of manufacturing the same

(75) Inventors: Young Jae Kim, Suwon (KR); Jae Woo Joung, Suwon (KR); Young Seuck Yoo, Seoul (KR)

(73) Assignee: SAMSUNG ELECTRO-MECHANICS CO., LTD., Suwon (KR)

(21) Appl. No.: 13/064,546

(22) Filed: Mar. 30, 2011

(30) Foreign Application Priority Data
Jul. 7, 2010 (KR) 10-2010-0065449

(51) Int. Cl. H05K 7/14; H05K 3/30; H05K 3/36; H05K 3/12

(52) U.S. Cl. 361/736; 29/832; 29/846

(57) ABSTRACT

Disclosed are an electronic component module and a method of manufacturing the same. The electronic component module includes a first insulating layer having a first surface in which first circuit patterns are embedded, electronic components of different kinds, the electronic components being mounted on the first circuit patterns and having electrode parts placed in different locations, and a molding layer encompassing the electronic components. Accordingly, a thin-film type electronic component module having a thin insulating layer with a circuit pattern can be provided.

### CROSS-REFERENCE TO RELATED APPLICATIONS

This application claims the priority of Korean Patent Application No. 10-2010-0065449 filed on Jul. 7, 2010, in the Korean Intellectual Property Office, the disclosure of which is incorporated herein by reference.

### BACKGROUND OF THE INVENTION

1. Field of the Invention

The present invention relates to an electronic component module, and more particularly, to a method of manufacturing an electronic component module, capable of providing an electronic component module in the form of a thin film and simplifying a manufacturing process.

2. Description of the Related Art

A printed circuit board (PCB) is prepared by disposing a circuit pattern on an insulating material, such as an insulating plate formed of a phenol resin or an epoxy resin. PCBs serve to electrically connect components, mounted on the printed circuit board, while mechanically fixing those components thereto.

Nowadays, electronic products are being developed to be miniaturized, thinned and packaged at a higher density. To cope with this current trend, PCBs are also being subjected to fine patterning, miniaturization and packaging.

For the formation of fine patterns, or to enhance reliability and increase design density, PCBs are evolving to have the complex layer configuration of a circuit while undergoing changes in their raw materials. In this respect, electronic components have also been changed from a Dual In-Line Package (DIP) type to a Surface Mount Technology (SMT) type, thereby increasing mounting density.

PCBs may be categorized into single-sided PCBs, in which a circuit layer is formed on only one side of an insulating substrate, double-sided PCBs, in which circuit layers are respectively formed on both sides thereof, and Multi Layered Boards (MLBs) having multilayered interconnections.

Typical methods for forming circuit patterns on insulating substrates include a subtractive method, an additive method, a semi-additive method, a modified semi-additive method and the like.

However, the above methods, used to fabricate printed circuit boards, require complicated processes of forming a multilayer plate, applying a resist thereto, etching the resist, washing the resultant structure, and the like. Those processes are significantly time-consuming and, moreover, may produce liquid that brings about environmental pollution.

For this reason, of late, a PCB fabrication technique that implements circuit patterns by printing conductive ink directly onto an insulating substrate through inkjet printing has been utilized. This PCB fabrication technique adopting inkjet printing is increasingly utilized due to its considerably simplified process and capability to reduce environmental pollution.

### SUMMARY OF THE INVENTION

An aspect of the present invention provides an electronic component module in the form of a thin film, and also provides a method of manufacturing an electronic component module, capable of simplifying a manufacturing process thereof.

According to an aspect of the present invention, there is provided an electronic component module including: a first insulating layer having a first surface on which first circuit patterns are embedded; electronic components of different kinds, the electronic components being mounted on the first circuit patterns and having electrode parts placed in different locations; and a molding layer encompassing the electronic components.

The first insulating layer may have a thickness ranging from 10 μm to 200 μm.

Each of the electronic components may be a resistor, a condenser or a semiconductor chip.

The first insulating layer may have a second surface opposing the first surface and having second circuit patterns electrically connected with the first circuit patterns.

The first insulating layer may have a second surface opposing the first surface and having second circuit patterns electrically connected with the first circuit patterns. The electronic component module may further include a second insulating layer placed on the first insulating layer and having third circuit patterns electrically connected with the second circuit patterns.

The electronic component module may further include an electronic component mounted on the third circuit patterns. The second insulating layer may have a thickness ranging from 10 μm to 200 μm.

According to another aspect of the present invention, there is provided a method of manufacturing an electronic component module, the method including: mounting an electronic component on a support substrate so as to cause an electrode part of the electronic component to face downwards; discharging an insulating resin by using an inkjet method to form a molding layer encompassing the electronic component; flipping the molding layer over with respect to the support substrate, so as to cause the electrode part of the electronic component to face upwards; forming first circuit patterns on the molding layer and the electrode part of the electronic component by using an inkjet method; and forming a first insulating layer on the first circuit pattern by using an inkjet method.

The electronic component may include electronic component modules of different kinds in which electrode parts thereof are placed in different locations.

The electronic component may be mounted after an adhesive film is disposed on the support substrate.

The method may further include forming a second circuit pattern on the first insulating layer by using an inkjet method, the second circuit pattern being electrically connected with the first circuit pattern.

The method may further include: forming a second circuit pattern on the first insulating layer by using an inkjet method, the second circuit pattern being electrically connected with the first circuit pattern; and forming a second insulating layer on the first insulating layer, the second insulating layer having a third circuit pattern electrically connected with the second circuit pattern by using an inkjet method.

The method may further include mounting an electronic component on the third circuit pattern.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view illustrating an electronic component module according to an exemplary embodiment of the present invention;

FIG. 2 is a schematic cross-sectional view illustrating an electronic component module according to another exemplary embodiment of the present invention;

FIGS. 3A through 3H are cross-sectional views illustrating the respective processes of a method of manufacturing an electronic component module according to an exemplary embodiment of the present invention; and

FIGS. 4A through 4C are cross-sectional views illustrating the respective processes of a method of manufacturing an electronic component module according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of element may be exaggerated for clarity. Like reference numerals in the drawings denote like elements.

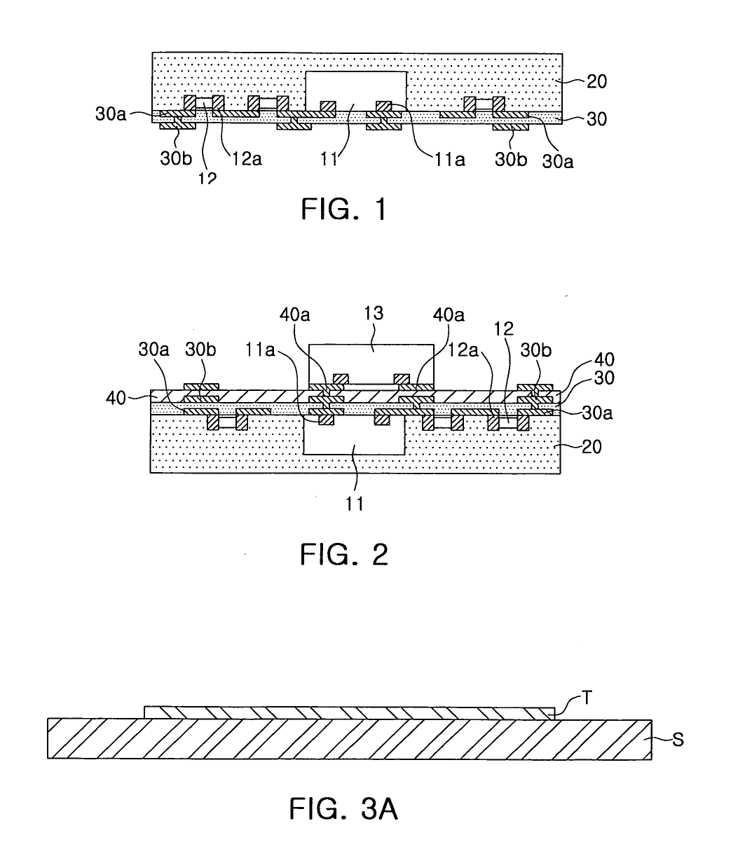

FIG. 1 is a schematic cross-sectional view illustrating an electronic component module according to an exemplary embodiment of the present invention.

Referring to FIG. 1, an electronic component module, according to this exemplary embodiment, includes a first insulating layer 30, electronic components 11 and 12 mounted on the first insulating layer 30, and a molding layer 20 surrounding the electronic components 11 and 12.

The first insulating layer 30 has a first surface in which first circuit patterns 30a are embedded. To form the first insulating layer 30, an insulating resin is discharged by an inkjet method to cover the first circuit patterns 30a formed on the electrode parts of the electronic components 11 and 12.

The method of forming the first insulating layer 30 will be described later in detail.

The first insulating layer 30 has a second surface opposing the first surface in which the first circuit patterns 30a are embedded. Second circuit patterns 30b may be formed on the second surface. The first and second circuit patterns 30a and 30b may be electrically connected together through via holes formed in the first insulating layer 30.

The first insulating layer 30, although not limited thereto, may utilize a polyimide-based resin, an epoxy-based resin, a polyester-based resin, a phenol resin, or an ultraviolet (W)-curable resin.

The first insulating layer 30 may have a thickness ranging from 10 μl to 200 μm; however, it is not limited thereto.

According to this exemplary embodiment in association with manufacturing processes to be described later, a thin insulating layer including first circuit patterns may be formed, and electronic components may be mounted on this insulating layer at a high density. This allows an electronic component module to be provided in the form of a thin film (hereinafter, also referred to as a thin-film type electronic component module).

Electronic components 11 and 12 of different kinds in which electrode parts are placed in different locations are mounted on the first circuit patterns 30a. The second circuit patterns 30b may serve to apply external power to the electronic components 11 and 12 mounted on the first circuit patterns 30a.

According to this exemplary embodiment, each of the electronic components 11 and 12 may be a resistor, a condenser, a semiconductor chip or the like.

The molding layer 20 encompasses the electronic components 11 and 12. This molding layer 20 may serve to fix and protect electronic components of different kinds from external conditions. According to this exemplary embodiment, even if the electronic components 11 and 12 have different sizes or have electrode parts placed in different locations, the molding layer 20 may fix the electronic components 11 and 12 and allow the respective electrode parts 11 and 12a of the electronic components 11 and 12 to be placed on the same level and thus be mounted on the first circuit patterns 30a of the first insulating layer 30.

FIG. 2 is a schematic cross-sectional view illustrating an electronic component module according to another exemplary embodiment of the present invention. The same reference numerals as in the above embodiment indicate the same elements, and the following description will be mainly associated with different elements.

Referring to FIG. 2, an electronic component module, according to this exemplary embodiment, includes the first insulating layer 30, the electronic components 11 and 12 placed on the first surface of the first insulating layer 30, the molding layer 20 encompassing the electronic components 11 and 12, and a second insulating layer 40 placed on the first insulating layer 30.

Third circuit patterns 40a may be placed on the second insulating layer 40. Here, the third circuit patterns 40a are electrically connected with the second circuit patterns 30b on the second surface of the first insulating layer 30. The second and third circuit patterns 30b and 40a are electrically connected to each other through via holes formed in the first insulating layer 30.

Furthermore, an electronic component 13 may be mounted on the third circuit patterns 40a placed on the second insulating layer 40.

The second insulating layer 40 may utilize a polyimide-based resin, an epoxy-based resin, a polyester-based resin, a phenol resin or a UV curable resin; however, it is not limited thereto.

The second insulating layer 40, although not limited thereto, may have a thickness ranging from 10 μm to 200 μm.

This exemplary embodiment provides a thin-film type electronic component module with a multilayer circuit pattern.

Hereinafter, a method of manufacturing an electronic component module according to an exemplary embodiment of the present invention will be described.

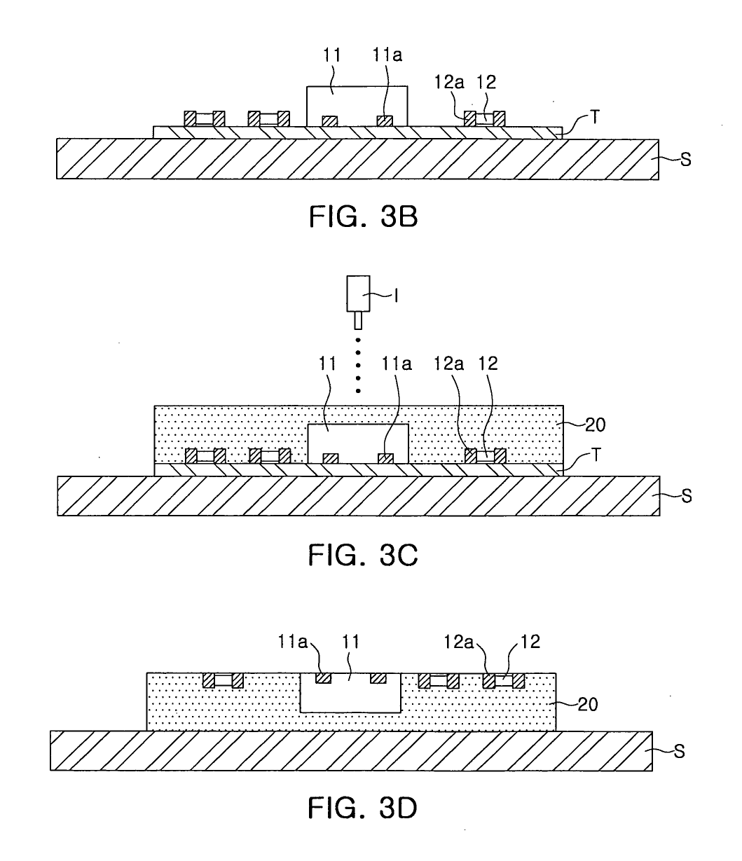

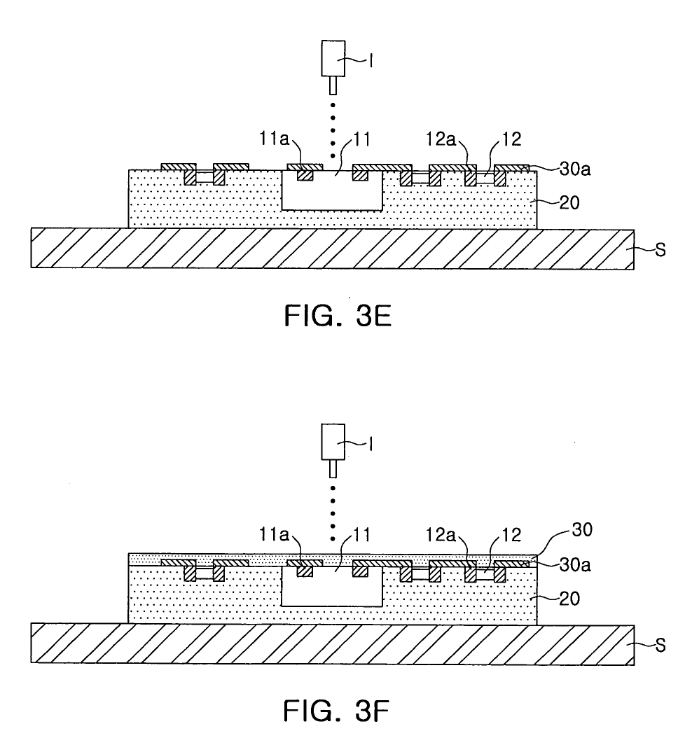

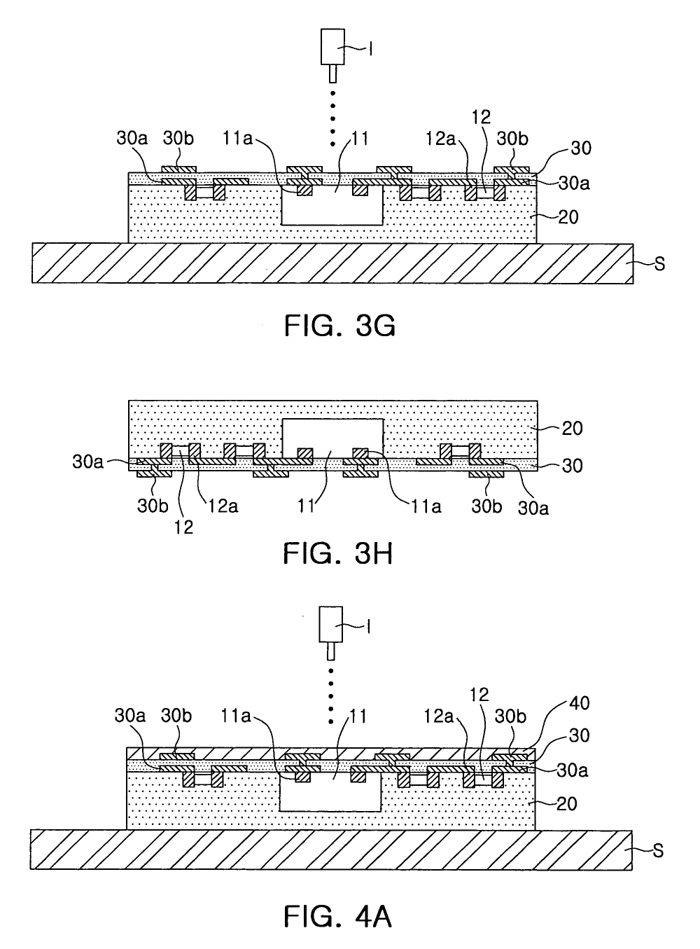

FIGS. 3A through 3H are cross-sectional views for explaining a method of manufacturing an electronic component module according to an exemplary embodiment of the present invention.

First, as shown in FIG. 3A, an adhesive film T is placed on a support substrate S. The support substrate S does not constitute an electronic component module, and it may be understood as a workbench for the subsequent processes.

Thereafter, as shown in FIG. 3B, the electronic components 11 and 12 are mounted on the adhesive film T. The electronic components 11 and 12 may utilize electronic components of different kinds in which electrode parts are placed in different locations.

Here, the electronic components 11 and 12 are placed in such a way that the electrode parts 11a and 12a thereof face downwards and come into contact with the adhesive film T. Thus, a plurality of electronic components may all have electrode parts placed on the same level, regardless of the sizes of electronic components and the locations of electrode parts.

The mounted electronic components 11 and 12 may be fixed by the use of the adhesive film T. This facilitates the subsequent processes. However, the process of forming the adhesive film T is not necessarily required, and an electronic component may be mounted directly on the support substrate S.

As shown in FIG. 3C, the molding layer 20 is formed by an inkjet method so as to encompass the electronic components 11 and 12 mounted on the adhesive film T.

To form the molding layer 20, an insulating resin is discharged onto the electronic components 11 and 12 through an inkjet print head I, and is then cured.

The insulating resin, although not limited thereto, may utilize a polyimide-based resin, an epoxy-based resin, a polyester-based resin, a phenol resin, or a UV curable resin.

The inkjet method may be a pressure vibration method, a charge control method, a thermal conversion method or the like. The above-mentioned methods may be used freely.

According to this exemplary embodiment, the electrode parts of electronic components contact the adhesive film while facing downwards. Accordingly, no insulating resin is formed around the electrode parts of the electronic components, and this may facilitate the process of forming circuit patterns on the electrode parts of the electronic components.

Thereafter, as shown in FIG. 3D, the molding layer 20 is flipped over with respect to the support substrate S such that the electrode parts 11a and 12a of the electronic components 11 and 12 face upwards.

The electronic components 11 and 12 are fixed by the molding layer 20, and the electrode parts 11a and 12b of the electrode components 11 and 12 face upwards while being placed on the same level with each other.

Accordingly, subsequent processes for forming circuit patterns on the electrode parts of the electrode components can be easily carried out.

Thereafter, as shown in FIG. 3E, the first circuit patterns 30a are formed on the molding layer 20 and the electrode parts 11a and 12a of the electronic components 11 and 12 by using an inkjet method.

Here, the first circuit patterns 30a may be formed by discharging conductive ink onto the molding layer 20 and the electrode parts 11a and 12a of the electronic components through an inkjet print head I, and then curing the conductive ink.

The conductive ink, although not limited thereto, may utilize a conductive polymer.

Subsequently, as shown in FIG. 3F, the first insulating layer 30 is formed on the first circuit patterns by using an inkjet method.

Here, the first insulating layer 30 may be formed by discharging an insulating resin through the inkjet print head I so as to cover the first circuit patterns 30a and then curing the insulating resin. Accordingly, the first circuit patterns 30a are embedded in the first insulating layer 30.

The insulating resin, although not limited thereto, may utilize a polyimide-based resin, an epoxy-based resin, a polyester-based resin, a phenol resin, or a UV-curable resin.

Thereafter, as shown in FIG. 3G, the second circuit patterns 30b, electrically connected with the first circuit patterns 30a, are formed by using an inkjet method.

After the formation of the first insulating layer 30, via holes may be formed to be connected with the first circuit patterns 30a. The via holes may be formed by using a known method such as photolithography and a laser.

Subsequently, conductive ink is discharged onto the via holes and the first insulating layer 30 through the inkjet print head I, and the conductive ink is then cured, thereby forming the second circuit patterns 30b.

Thereafter, the support substrate S is separated, thereby manufacturing an electronic component module as shown in FIG. 3H.

By repetitively conducting the above processes of forming the insulating layers and the circuit patterns, an electronic component module having a multilayered circuit pattern can be manufactured.

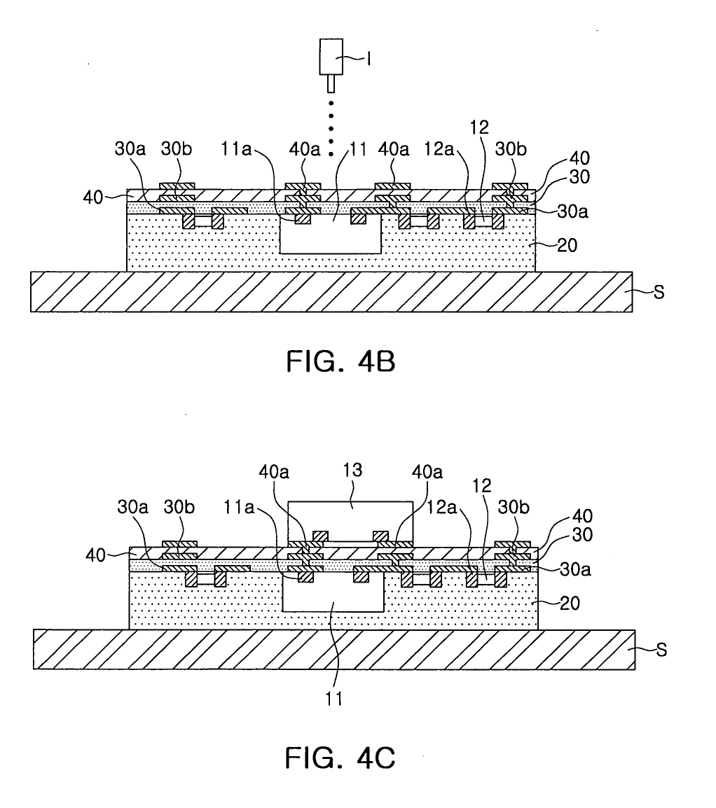

FIGS. 4A through 4C are cross-sectional views illustrating a method of manufacturing an electronic component module according to another exemplary embodiment of the present invention. In processes regarding this embodiment, the above-described processes of manufacturing an electronic component module may be performed consecutively. The following description will be made regarding processes after the process depicted in FIG. 3G.

As shown in FIG. 4A, the second insulating layer 40 is formed on the first insulating layer 30 by using an inkjet method.

The second insulating layer 40 may be formed by discharging an insulating resin through the inkjet print head I to cover the second circuit pattern 30b, and curing the insulating resin.

Subsequently, as shown in FIG. 4B, the third circuit patterns 40a are formed on the second insulating layer 40 by an inkjet method so as to be electrically connected to the respective second circuit patterns 30b.

After the formation of the second insulating layer 40, via holes may be formed for the connections with the second circuit patterns 30b. The via holes may be formed by using a known method such as photolithography or using a laser.

Thereafter, conductive ink is discharged into the via holes and on the insulating layer 40 through the inkjet print head I and the conductive ink is cured.

Thereafter, as shown in FIG. 4C, an electronic component 13 may be mounted so as to be electrically connected with the third circuit patterns 40a. Furthermore, a molding layer (not shown) may be further formed to encompass the electrode component 13. The process of forming such a molding layer may be conducted by using an inkjet method in the above mentioned manner.

Thereafter, the support substrate S is separated, thereby manufacturing an electronic component module as shown in FIG. 2.

As set forth above, according to exemplary embodiments of the invention, a thin insulating layer including circuit patterns can be formed, and electronic components can be densely mounted in the insulating layer, thereby allowing for the manufacturing of a thin-film type electronic module.

Furthermore, since insulating layers and circuit patterns are formed by using an inkjet method, an electronic component module can be manufactured through simple processes. Also, due to the characteristics of the manufacturing process according to exemplary embodiments of the invention, a molding layer can be freely formed, and a plurality of electronic components all have electrode parts placed on the same level regardless of the sizes of the electronic components and the locations in which their electrode parts are disposed. Accordingly, circuit patterns can be easily formed.

While the present invention has been shown and described in connection with the exemplary embodiments, it will be apparent to those skilled in the art that modifications and variations can be made without departing from the spirit and scope of the invention as defined by the appended claims.

What is claimed is:

1. An electronic component module comprising:
a first insulating layer having a first surface on which first circuit patterns are embedded;
electronic components of different kinds, the electronic components being mounted on the first circuit patterns and having electrode parts placed in different locations; and
a molding layer encompassing the electronic components.

2. The electronic component module of claim 1, wherein the first insulating layer has a thickness ranging from 10 μm to 200 μm.

3. The electronic component module of claim 1, wherein each of the electronic components is a resistor, a condenser or a semiconductor chip.

4. The electronic component module of claim 1, wherein the first insulating layer has a second surface opposing the first surface and having second circuit patterns electrically connected with the first circuit patterns.

5. The electronic component module of claim 1, wherein the first insulating layer has a second surface opposing the first surface and having second circuit patterns electrically connected with the first circuit patterns,
wherein the electronic component module further comprises a second insulating layer placed on the first insulating layer and having third circuit patterns electrically connected with the second circuit patterns.

6. The electronic component module of claim 5, further comprising an electronic component mounted on the third circuit patterns.

7. The electronic component module of claim 5, wherein the second insulating layer has a thickness ranging from 10 μm to 200 μm.

8. A method of manufacturing an electronic component module, the method comprising:
mounting an electronic component on a support substrate so as to cause an electrode part of the electronic component to face downwards;
discharging an insulating resin by using an inkjet method to form a molding layer encompassing the electronic component;
flipping the molding layer over with respect to the support substrate, so as to cause the electrode part of the electronic component to face upwards;
forming first circuit patterns on the molding layer and the electrode part of the electronic component by using an inkjet method; and
forming a first insulating layer on the first circuit pattern by using an inkjet method.

9. The method of claim 8, wherein the electronic component comprises electronic component modules of different kinds in which electrode parts thereof are placed in different locations.

10. The method of claim 8, wherein the electronic component is mounted after an adhesive film is disposed on the support substrate.

11. The method of claim 8, further comprising forming a second circuit pattern on the first insulating layer by using an inkjet method, the second circuit pattern being electrically connected with the first circuit pattern.

12. The method of claim 8, further comprising:
forming a second circuit pattern on the first insulating layer by using an inkjet method, the second circuit pattern being electrically connected with the first circuit pattern; and
forming a second insulating layer on the first insulating layer, the second insulating layer having a third circuit pattern electrically connected with the second circuit pattern on the first insulating layer by using an inkjet method.

13. The method of claim 12, further comprising mounting an electronic component on the third circuit pattern.
